(19) United States
(12) Patent Application Publication
(10) Pub. No.: US 2011/0140137 A1
(43) Pub. Date: Jun. 16, 2011

(54) LED DEVICE AND METHOD OF MANUFACTURING THE SAME

(75) Inventor: CHIH-CHEN LAI, Tu-Cheng (TW)

(73) Assignee: HON HAI PRECISION INDUSTRY CO., LTD., Tu-Cheng (TW)

(21) Appl. No.: 12/894,155

(22) Filed: Sep. 30, 2010

(30) Foreign Application Priority Data
Dec. 10, 2009 (CN) 200910311166.4

(51) Int. Cl. H01L 33/32; H01L 33/42

(52) U.S. Cl. 257/89; 438/35; 257/E33.025; 257/E33.064

(57) ABSTRACT

An LED device includes a heat conductive base, and a red, a green, and a blue LED chips mounted on the base. The red LED chip includes a first n-type GaN layer, a first p-type GaN layer, and a first active layer sandwiched therebetween. The first active layer of the red LED chip is added with europium to generate red light. The green LED chip includes a second n-type GaN layer, a second p-type GaN layer, and a second active layer sandwiched therebetween. The second active layer of the green LED chip is added with indium to generate green light. The blue LED chip includes a third n-type GaN layer, a third p-type GaN layer, and a third active layer sandwiched therebetween. The third active layer of the blue LED chip is added with of indium to generate blue light.

### BACKGROUND

1. Technical Field

The disclosure generally relates to light emitting diode (LED) devices; and more particularly to an LED device having different types of LED chips and a method of manufacturing the LED device.

2. Description of Related Art

Generally, red, blue and green types of LED chips are mounted on a single base to form an LED device to get white light. The green LED chips and blue LED chips are generally manufactured by fabricating a GaN-based semiconductor laminated structure on a sapphire substrate, and the red LED chips are generally manufactured by fabricating a GaAsP-based semiconductor laminated structure on a GaAs substrate. A thermal expansion coefficient of the red LED chip is different from the green and blue LED chips. Thus, the LED device, which has red, green and blue LED chips mounted on the single base, has a poor reliability after a period of use due to different residual thermal stresses therein.

What is needed, therefore, is an LED device and a manufacturing method thereof which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the several views.

FIG. 1 is a schematic view illustrating an LED device in accordance with an exemplary embodiment of the present disclosure.

FIG. 2 is a schematic view illustrating LED chips for forming the LED device of FIG. 1.

### DETAILED DESCRIPTION

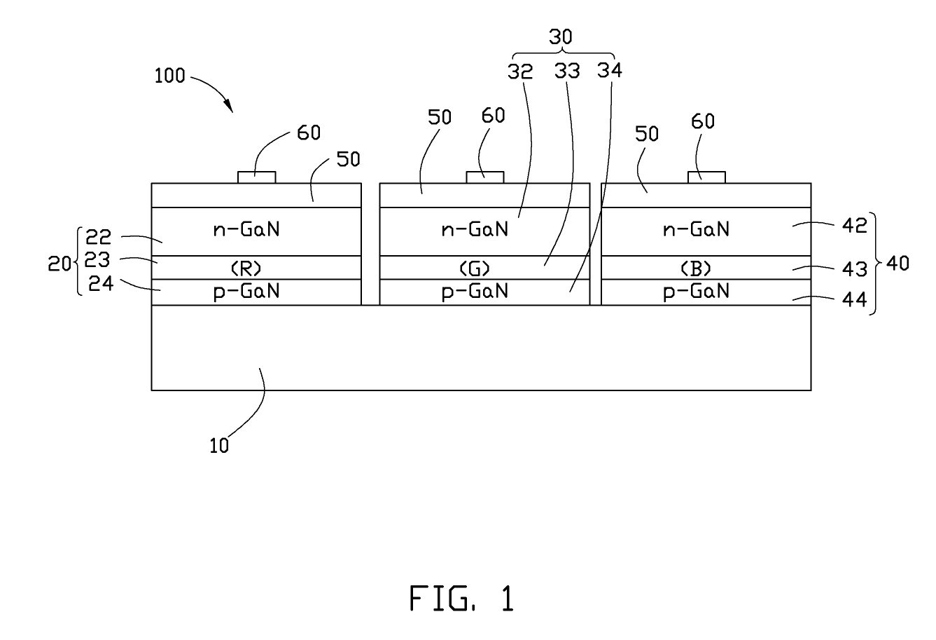

Referring to FIG. 1, an LED device 100 according to an exemplary embodiment of the present disclosure is shown. The LED device 100 includes a heat conductive base 10, a red LED chip 20 for emitting red light, a green LED chip 30 for emitting green light, and a blue LED chip 40 for emitting blue light. The red LED chip 20, the green LED chip 30 and the blue LED chip 40 are mounted on the heat conductive base 10.

The heat conductive base 10 is made of materials having good heat conductivity, such as copper, copper-alloy, aluminum, aluminum-alloy, nickel, carbon nanotubes, silicon and diamond.

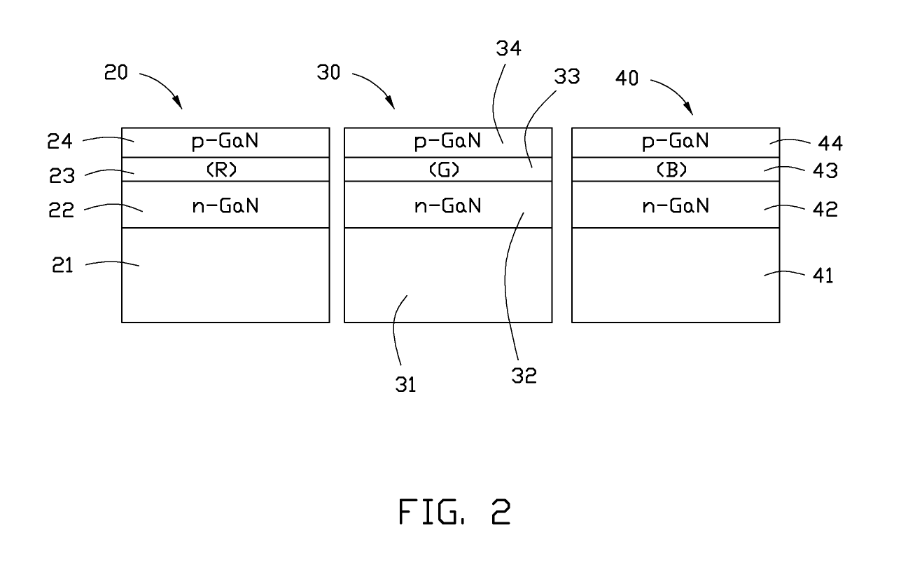

Referring also to FIG. 2, the red LED chip 20 is a GaN-based semiconductor laminated structure first formed on a substrate 21 before the red LED chip 20 is mounted on the conductive base 10. The red LED chip 20 includes an n-type GaN layer 22, a p-type GaN layer 24, and an active layer 23 sandwiched between the n-type GaN layer 22 and the p-type GaN layer 24 for generating light. The substrate 21 is made of sapphire. When manufacturing the red LED chip 20, the n-type GaN layer 22 is first formed on the substrate 21. Then, the active layer 23 and the p-type GaN layer 24 are sequentially formed on the n-type GaN layer 22. In the process of manufacturing the red LED chip 20, the active layer 23 is added with europium to generate red light.

The green LED chip 30 is a GaN-based semiconductor laminated structure formed on a substrate 31. The green LED chip 30 includes an n-type GaN layer 32, a p-type GaN layer 34, and an active layer 33 sandwiched between the n-type GaN layer 32 and the p-type GaN layer 34 for generating light. The substrate 21 is also made of sapphire. When manufacturing the green LED chip 30, the n-type GaN layer 32 is first formed on the substrate 31. Then, the active layer 33 and the p-type GaN layer 34 are sequentially formed on the n-type GaN layer 32. In the process of manufacturing the green LED chip 30, the active layer 33 is added with indium to generate green light.

The blue LED chip 40 is a GaN-based semiconductor laminated structure formed on a substrate 41. The blue LED chip 40 includes an n-type GaN layer 42, a p-type GaN layer 44, and an active layer 43 sandwiched between the n-type GaN layer 42 and the p-type GaN layer 44 for generating light. The substrate 21 is also made of sapphire. When manufacturing the blue LED chip 40, the n-type GaN layer 42 is first formed on the substrate 41. Then, the active layer 43 and the p-type GaN layer 44 are sequentially formed on the n-type GaN layer 42. In the process of manufacturing the blue LED chip 40, the active layer 43 is added with indium to generate blue light.

In assembly of the red LED chip 20 to the heat conductive base 10, the red LED chip 20 is inversely placed on the heat conductive base 10, with the p-type GaN layer 24 thereof facing the heat conductive base 10. The red LED chip 20 is coupled to the heat conductive base 10 by electroplating or bonding. Then, the substrate 21 is removed from the red LED chip 20 by laser lift-off technique. After the substrate 21 has been removed from the red LED chip 20, a transparent conductive layer 50 is formed on the n-type GaN layer 22, and then an electrical pad 60 is formed on the transparent conductive layer 50. A process of mounting the green LED chip 30 and a process of mounting the blue LED chip 40 are the same as the process of mounting the red LED chip 20.

In the LED device 100, the red LED chip 20, the green LED chip 30 and the blue LED chip 40 are formed on three separate substrates 21, 31, 41, respectively. Alternatively, the red LED chip 20, the green LED chip 30 and the blue LED chip 40 can be formed on a single substrate. Further, an amount and an arrangement of the red, the green and the blue LED chips 20, 30, 40 can be changed to satisfy optical requirements of the LED device 100.

In the LED device 100, all of the red, the green, the blue LED chips 20, 30, 40 are GaN-based semiconductor laminated structures formed on sapphire substrates 21, 31, 41. A manufacturing process of the red LED chip 20 is consistent with manufacturing processes of the green and the blue LED chips 30, 40, whereby thermal characteristic, for example, coefficient of thermal expansion, of the red LED chip 20 is similar to those of the green and the blue LED chips 30, 40. Thus, the LED device 100, which has the red, the green and the blue LED chips 20, 30, 40 mounted on the single heat conductive base 10, has a good reliability, even after a long period of use.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED device comprising:
a heat conductive base;
a red LED chip mounted on the heat conductive base, the red LED chip comprising a first n-type GaN layer, a first p-type GaN layer, and a first active layer sandwiched between the first n-type GaN layer and the first p-type GaN layer, the first active layer of the red LED chip being added with europium to generate red light;
a green LED chip mounted on the heat conductive base, the green LED chip comprising a second n-type GaN layer, a second p-type GaN layer, and a second active layer sandwiched between the second n-type GaN layer and the second p-type GaN layer, the second active layer of the green LED chip being added with indium to generate green light; and
a blue LED chip mounted on the heat conductive base, the blue LED chip comprising a third n-type GaN layer, a third p-type GaN layer, and a third active layer sandwiched between the third n-type GaN layer and the third p-type GaN layer, the third active layer of the blue LED chip being added with indium to generate blue light.

2. The LED device of claim 1, wherein each of the red LED chip, the green LED chip and the blue LED chip is a GaN-based semiconductor laminated structure formed on a sapphire substrate before the red LED chip, the green LED chip and the blue LED chip are mounted to the heat conductive base.

3. The LED device of claim 1, wherein the first p-type GaN layer of the red LED chip, the second p-type GaN layer of the green LED chip and the third p-type GaN layer of the blue LED chip are coupled to the heat conductive base.

4. The LED device of claim 3, wherein a transparent conductive layer is formed on each of the first n-type GaN layer of the red LED chip, the second n-type GaN layer of the green LED chip and the third n-type GaN layer of the blue LED chip, and an electrical pad is formed on the transparent conductive layer.

5. The LED device of claim 1, wherein the heat conductive base is made of one of the following materials: copper, copper-alloy, aluminum, aluminum-alloy, nickel, carbon nanotubes, silicon and diamond.

6. A method for manufacturing an LED device, comprising steps of:
providing a red LED chip, the red LED chip comprising a first n-type GaN layer, a first active layer and a first p-type GaN layer sequentially formed on a first sapphire substrate, the first active layer of the red LED chip being added with europium to generate red light;
providing a green LED chip, the green LED chip comprising a second n-type GaN layer, a second active layer and a second p-type GaN layer sequentially formed on a second sapphire substrate, the second active layer of the green LED chip being added with indium to generate green light;
providing a blue LED chip, the blue LED chip comprising a third n-type GaN layer, a third active layer and a third p-type GaN layer sequentially formed on a third sapphire substrate, the third active layer of the blue LED chip being added with indium to generate blue light; and
providing a heat conductive base and coupling the red LED chip, the green LED chip and the blue LED chip to the heat conductive base.

7. The method of claim 6, wherein the first p-type GaN layer of the red LED chip, the second p-type GaN layer of the green LED chip and the third p-type GaN layer of the blue LED chip are coupled to the heat conductive base.

8. The method of claim 6, further comprising removing the first sapphire substrate from the red LED chip, the second sapphire substrate from the green LED chip and the third sapphire substrate from the blue LED chip after coupling the red LED chip, the green LED chip and the blue LED chip to the heat conductive base.

9. The method of claim 8, further comprising forming a transparent conductive layer on each of the first n-type GaN layer of the red LED chip, the second n-type GaN layer of the green LED chip and the third n-type GaN layer of the blue LED chip after removing the first sapphire substrate from the red LED chip, the second sapphire substrate from the green LED chip and the third sapphire substrate from the blue LED chip.

10. The method of claim 9, further comprising forming an electrical pad on the transparent conductive layer.

11. The LED device of claim 6, wherein the heat conductive base is made of one of the following materials: copper, copper-alloy, aluminum, aluminum-alloy, nickel, carbon nanotubes, silicon and diamond.
